(19) United States
(12) Patent Application Publication
(10) Pub. No.: US 2006/0227514 A1
(43) Pub. Date: Oct. 12, 2006

(54) Digital micro-mirror device (DMD) assembly for an optical projection system

(75) Inventors: Byung-jo Kang, Suwon-si (KR); Kyoung-choul Jang, Suwon-si (KR); Heong-seog Lee, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/357,135

(22) Filed: Feb. 21, 2006

(30) Foreign Application Priority Data
Apr. 8, 2005 (KR) 2005-29379

(51) Int. Cl. H05K 7/20

(52) U.S. Cl. 361/719; 361/695

(57) ABSTRACT

A digital micro-mirror assembly for an optical projection system includes a DMD module with a control board. The control board is provided with a first fixing member, and a DMD is mounted on one side of the control board. A DMD holder resiliently supports a perimeter of the DMD, and an optical holder is provided with a second fixing member to support the DMD module. A fastening member is engaged with the first and the second fixing members to integrally connect the DMD module and the optical holder.

### CROSS-REFERENCE TO RELATED APPLICATIONS

This application claims the benefit under 35 U.S.C. §119(a) of Korean Patent Application No. 2005-29379, filed Apr. 8, 2005, the entire contents of which are hereby incorporated by reference.

### BACKGROUND OF THE INVENTION

1. Field of the Invention

The present invention relates to an optical projection system. More particularly, the present invention relates to a digital micro-mirror device (DMD) assembly for an optical projection system that has an improved structure.

2. Description of the Related Art

Optical projection systems are used to project a small image onto a relatively large, wide screen using an optical device. Optical projection systems can be generally divided into three types of systems: cathode ray tube (CRT) projection systems, a liquid crystal display (LCD) projection systems, and digital light processing (DLP) projection systems.

The CRT projection system is the oldest type of system. It projects an enlarged image by using a mirror to reflect an image produced on a small high-definition CRT onto a screen. In an LCD projection system, an external reproduction image signal is transmitted to a projection TV, and a small LCD screen (approximately 4 inches in diameter) receives the external reproduction image signal in the projection TV to form an image. The image formed on the LCD screen is enlarged by irradiating a strong light from behind the LCD screen through a lens, reflected the light with a mirror, and projecting the reflected light onto a screen.

A DLP projection system projects an externally input image signal using a DMD semiconductor chip in which hundreds of thousands of micro-mirrors are integrated. In the DLP projection system, an assembly comprising a heat sink, a DMD module (including a control board and a DMD) and an optical holder uses a flexible assembly system. The flexible assembly system restricts the arrangement of the heat sinks to prevent the heat sinks from applying excessive pressure to and damaging the DMD module.

One flexible assembly system is disclosed in U.S. Pat. No. 6,791,838, which was filed on Sep. 15, 2004 and is assigned on its face to the Lite-On Technology Corporation. This patent is hereby incorporated by reference in its entirety.

FIG. 1 shows the structure of the flexible assembly system disclosed in the U.S. Pat. No. 6,791,838. Referring to FIG. 1, the flexible assembly system comprises a heat sink 1, a DMD module 2, an optical holder 3, a flexible element 4, and a fastening element 5.

The heat sink 1 comprises a plurality of connection holes 10, a thermal conductor 11 that protrudes from a lower portion of the heat sink, and a heat sink pin 12.

The DMD module 2 comprises a control board 20, a DMD 21, an upper cover 23 transmitting information from the control board 20 to the DMD 21, and a fixing holder 22 disposed around the DMD 21. The control board 20 has a board opening 200 and a first fastening hole 201a. The upper cover 23 has a cover opening 230 formed to correspond to the thermal conductor 11 of the heat sink 1. The thermal conductor 11 of the heat sink 1 penetrates the board opening 200 of the control board 200 and contacts a rear portion 210 of the DMD 21 which controls the angles of the plurality of micro-mirrors 211.

The optical holder 3 has a second fastening-hole 30a and an assembly interface 31a for assembling the DMD module 2.

The flexible element 4 comprises a plurality of compressing springs 4a, whereas the fastening element 5 comprises a plurality of bolts 5a.

FIG. 2 illustrates the structure of another conventional DMD assembly.

Referring to FIG. 2, the DMD assembly comprises the heat sink 1, the DMD module 2, the optical holder 3, the flexible element 4 and the fastening element 5. Since the DMD assembly is constructed similarly to the flexible assembly system of FIG. 1, the same elements will be cited by the same reference numerals and detailed description will not be repeated.

In contrast to the DMD assembly of FIG. 1, the DMD assembly of FIG. 2 has a flat spring 250 and a nut 260. The flat spring 250 buffers pressure applied to the DMD module 2 when the assembly is connected to reduce damage to the DMD 21. The nut 260 enhances the connection.

The conventional DMD assemblies described above have complicated structures, comprising the flexible element 4, the compressing springs 4a, the flat spring 250 and special screws such as the bolts 5a. As a consequence, the manufacturing process is relatively complicated. Further, adjusting the position of the DMD 21 is difficult with these conventional structures. Also, in these structures, the DMD 21 can be exposed to dust, and image quality may deteriorate.

Accordingly, there is a need for a simpler structure for a digital micro-mirror device (DMD) assembly for an optical projection system that is easier to manufacture, easier to adjust, and minimizes exposure to dust.

### SUMMARY OF THE INVENTION

An aspect of the present invention is to address at least the above problems and/or disadvantages and to provide at least the advantages described below. Accordingly, an aspect of the present invention is to provide a digital micro-mirror device (DMD) assembly for an optical projection system that has an an improved structure for simpler manufacturing.

Another aspect of the present invention is to provide a DMD assembly for an optical projection system that is prevents the deterioration of image quality by adding a substantially dustproof structure.

In accordance with an exemplary embodiment of the present invention, a DMD assembly comprises a DMD module with a control board that has a first fixing member. A DMD is mounted on one side of the control board, and a DMD holder resiliently supports a perimeter of the DMD. An optical holder is provided with a second fixing member to support the DMD module. A fasteninig member is engaged with the first and the second fixing members to integrally connect the DMD module and the optical holder.

The DMD holder may have a DMD holder opening in the center thereof, and the DMD holder opening may be provided with a plurality of decentralizing holes.

The control board may be provided with a bracket plate on the side opposite to the side where the DMD is mounted. The bracket plate may have a third fixing member to integrally connect the bracket plate, the DMD module and the optical holder through the fastening member.

The fastening member may comprise a plurality of screws. The first fixing member may comprise a plurality of board connection holes formed on the control board for engagement with the screws. The third fixing member may comprise a plurality of bracket plate connection holes formed on the bracket plate. The DMD holder may be provided with a plurality of via-holes for penetration of the screws.

The bracket plate is preferably made of aluminum. The bracket plate may be connected with a heat sink by a heat sink supporting unit and may be provided with a bracket plate opening so that a rear portion of the DMD can contact with the heat sink.

The heat sink supporting unit may comprise a plurality of hooks formed on a peripheral end of the bracket plate. A flat spring may support the heat sink and have hook recesses at opposite ends for engaging the hooks.

The heat sink may be further provided with a cooling fan on one side which is supported by a fan supporting unit. The fan supporting unit may comprise a cooling fan supporting boss protruding from the bracket plate, a fan holder inserted in the cooling fan supporting boss, and a fan bracket engaged with the fan holder at opposite ends of the bracket and connected to a bottom of the cooling fan.

A substantially dustproof unit may be provided between the DMD holder and the optical holder. The substantially dustproof unit may comprise a gasket that surrounds the DMD holder opening of the DMD holder. The gasket may be formed of resilient material. At least one of the optical holder and the DMD holder may be provided with a groove for receiving the gasket.

The DMD assembly may further comprise a housing that encloses the DMD module and the DMD holder. The holder may have a plurality of housing connection holes thereon, and wherein the optical holder may further comprise a housing boss having boss holes corresponding to the housing connection holes, so that the housing and the optical holder can be integrally connected with each other. The housing may comprise a plurity of cooling holes. The housing is preferably formed of metal so as to shield electromagnetic interference (EMI). The housing connection holes may be formed larger than the boss holes so that the position of the housing can be adjusted.

According to the above-described DMD assembly of the optical projection system in accordance with an exemplary embodiment of the present invention, the assembly of the DMD is easier because dedicated structures such as a flat spring and a special screw for connection are omitted.

Furthermore, since foreign substances such as dust are prevented from flowing into the DMD by the substantially dustproof unit, image quality can be improved.

In addition, the position of the DMD can be adjusted easily by varying the fastening position of the housing which includes the DMD.

### BRIEF DESCRIPTION OF THE DRAWING FIGURES

The above and other objects, features, and advantages of certain embodiments of the present invention will be more apparent from the following description taken in conjunction with the accompanying drawings, in which:

FIG. 1 is an exploded view of the structure of a flexible assembly system disclosed in U.S. Pat. No. 6,791,838;

FIG. 2 is an exploded view of the structure of another conventional digital micro-mirror device (DMD) assembly;

FIGS. 3 and 4 are perspective views of the structure of an optical engine using a DMD assembly according to an exemplary embodiment of the present invention;

FIG. 5 is an exploded, perspective view of the structure of the DMD assembly according to an exemplary embodiment of the present invention;

FIG. 6 is a partially enlarged view of a DMD holder according to an exemplary embodiment of the present invention, viewed in the direction of the arrow A in FIG. 5;

FIG. 7 is a front view illustrating the structure of a bracket plate according to an exemplary embodiment of the present invention, viewed in the direction of the arrow B of FIG. 5;

FIG. 8 is an enlarged view of the portion ‘V’ of FIG. 5;

FIG. 9 shows a heat sink being connected, according to an exemplary embodiment of the present invention; and

FIG. 10 is an enlarged view of a portion ‘VI’ of FIG. 5 that shows a substantially dustproof unit applied in accordance with an exemplary embodiment of the present invention.

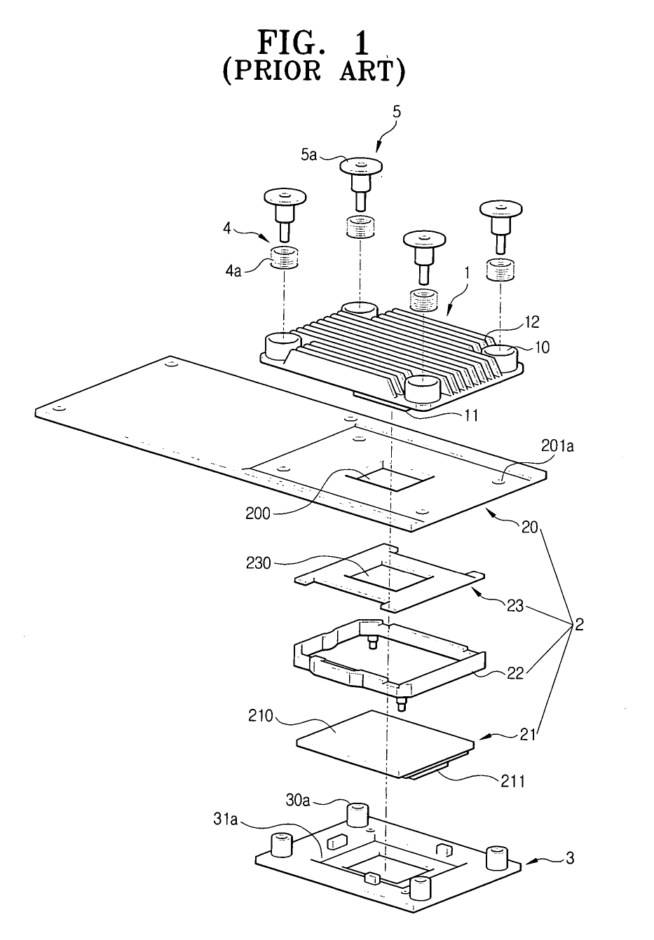

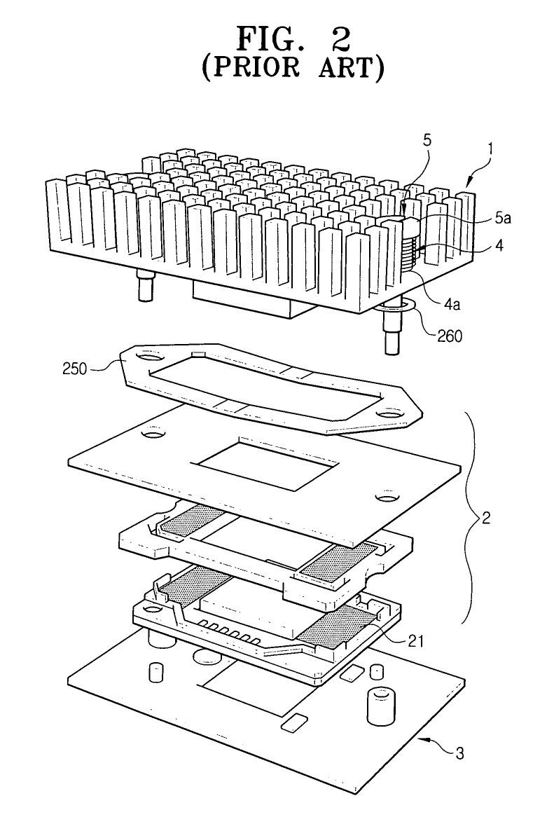

Throughout the drawings, the same drawing reference numerals will be understood to refer to the same elements, features, and structures.

### DETAILED DESCRIPTION OF EXEMPLARY EMBODIMENTS

The matters defined in the description such as a detailed construction and elements are provided to assist in a comprehensive understanding of the embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

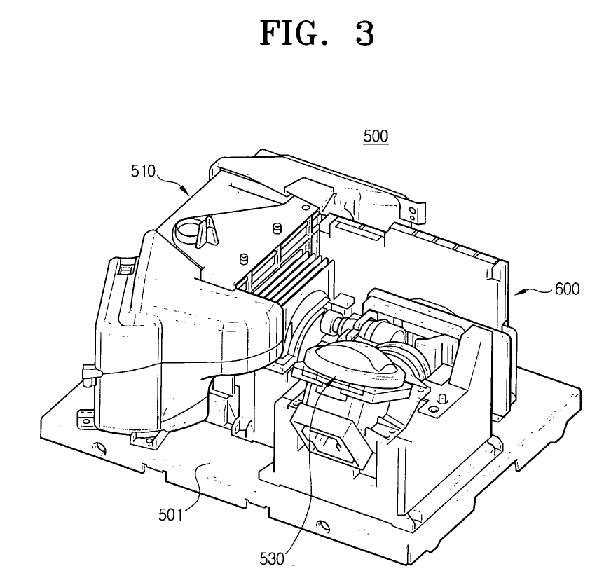

FIG. 3 is a perspective view showing the structure of an optical engine with a digital micro-mirror device (DMD) assembly according to an exemplary embodiment of the present invention. Referring to FIG. 3, an optical engine 500 comprises a base 501, a lighting unit 510, a DMD assembly 600, and a projection lens unit 530. A light projected from the lighting unit 510 is reflected from a DMD of the DMD assembly 530 toward the projection lens unit 530. The DMD will be described in detail later. An image light reflected to the projection lens unit 530 is projected onto a projection surface such as a screen (not shown).

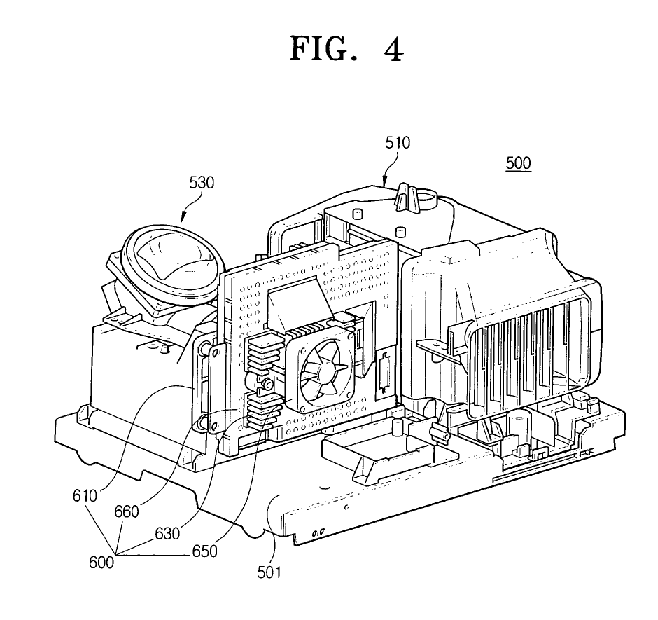

FIG. 4 is a perspective view illustrating the structure of the DMD assembly 600 according to an exemplary embodiment of the present invention. Referring to FIG. 4, an optical holder 610 which forms part of the DMD assembly 600 is erected on the base 501. The optical holder 610 includes a DMD module which will be described later. A housing 660, which is connected with a heat sink 630 and a cooling fan 650, is attached on the outside of the optical holder 610.

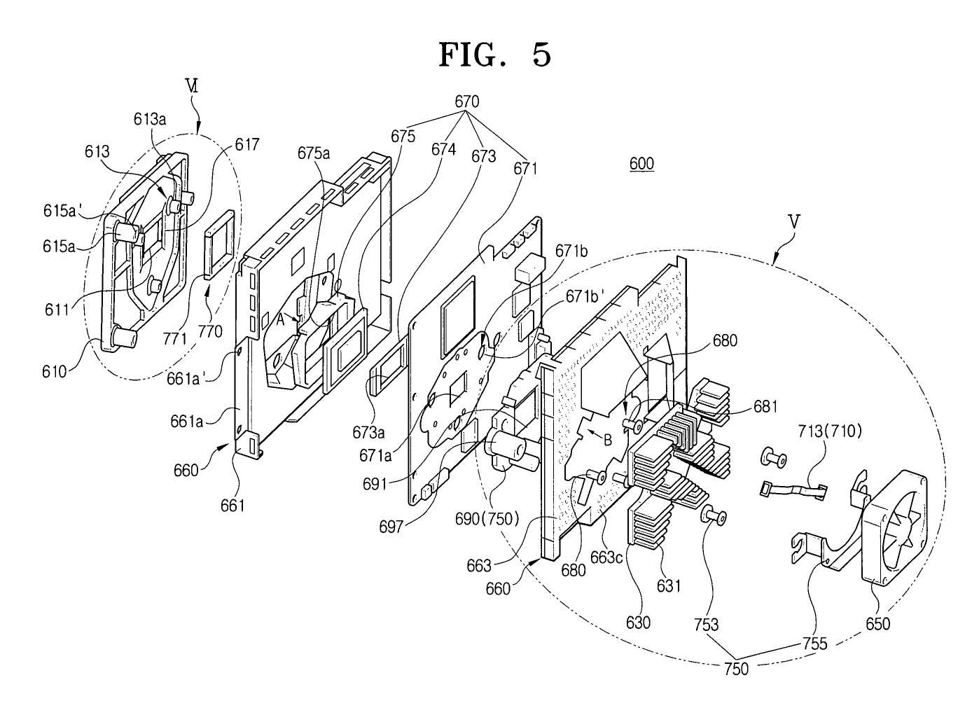

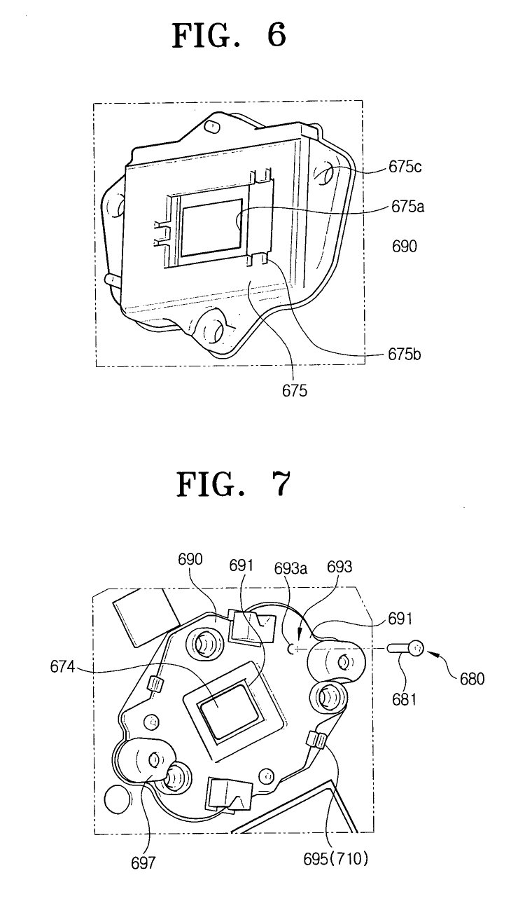

FIG. 5 is an exploded, perspective view showing the structure of the DMD assembly 600. FIG. 6 is an enlarged view of a DMD holder according to an exemplary embodiment of the present invention.

Referring to FIG. 5, the DMD assembly 600 comprises the optical holder 610, the heat sink 630, the cooling fan 650, the housing 660, the DMD module 670, and a fastening member 680.

The housing 660 encloses the DMD module 670. To this end, the housing 660 comprises a pair of square boxes, that is, first and second square boxes 661 and 663. The first square box 661 includes a connection piece 661a that extends from a peripheral end of the housing 600 and has a plurality of housing connection holes 661a′. The second square box 663 forming the housing 660 has a plurality of cooling holes 663c to emit heat generated from the DMD module 670 formed therein. The housing 660 is preferably formed of metal so as to effectively shield electromagnetic interference (EMI).

The DMD module 670 comprises a control board 671, a socket 673 mounted on one side of the control board 671, a DMD 674 in which numerous micro-mirrors are arranged, and a DMD holder 675 resiliently surrounding and supporting the DMD 674. Here, the DMD holder 675 decentralizes a force applied to the DMD 674 during assembly of the DMD assembly 670.

The socket 673 and the control board 671 respectively have a socket opening 673a and a board opening 671a to allow the rear portion of the DMD 674 to penetrate through. Additionally, the control board 671 is provided with a first fixing member 67 lb, such as a plurality of board connection holes 671b’ , to fix the fastening member 680.

Referring to FIG. 6, the DMD holder 675 has a DMD holder opening 675a in its center portion and a plurality of decentralizing holes 675b for evenly dividing the force applied to the DMD 674 by resiliently supporting the DMD 674. Additionally, the DMD holder 675 has via-holes 675c to allow the fastening member 680 to pass through.

Referring back to the FIG. 5, the optical holder 610 has an optical holder opening 611 and a plurality of connection bosses 613a to form a second fixing member 613 to fix the fastening member 680. In addition, a housing boss 615a is provided around the optical holder 610, which has a boss holes 615a′ corresponding to the housing connection holes 661 a′ formed on the connection piece 661a, so as to integrate the housing 660 and the optical holder 610. Preferably, the housing connection holes 661a′ are larger than the boss holes 615a’ so that the housing 660 can move vertically or horizontally, thereby positioning the DMD 674 built in the housing 660.

The fastening member 680 comprises screws 681 for engagement with the board connection holes 671b′ (which are the first fixing member 671b) and with the connection bosses 613a (which are the second fixing member 613). Accordingly, the fastening member 680 integrates the DMD module 670 (including the control board 671, the socket 673 and the DMD 674), with the optical holder 610.

A bracket plate 690 may be further provided on an opposite side of the control board 671 to the side where the DMD 674 is mounted.

FIG. 7 is a front view of the bracket plate 690 according to one exemplary embodiment of the present invention. Referring to FIG. 7, the bracket plate 690 has a bracket plate opening 691 and a third fixing member 693 for engagement with the screws 681 (which are the fastening member 680). The third fixing member 693 comprises a plurality of bracket plate connection holes 693a to allow the screws 681 to pass through. Accordingly, the optical holder 610, the DMD module 670, the control board 671 and the bracket plate 690 can all lie integrated by the screws 681.

The bracket plate 690 is structured to mount an air-expelling device such as the heat sink 630 and the cooling fan 650. The mounting structure of such an air-expelling device will now be described in greater detail.

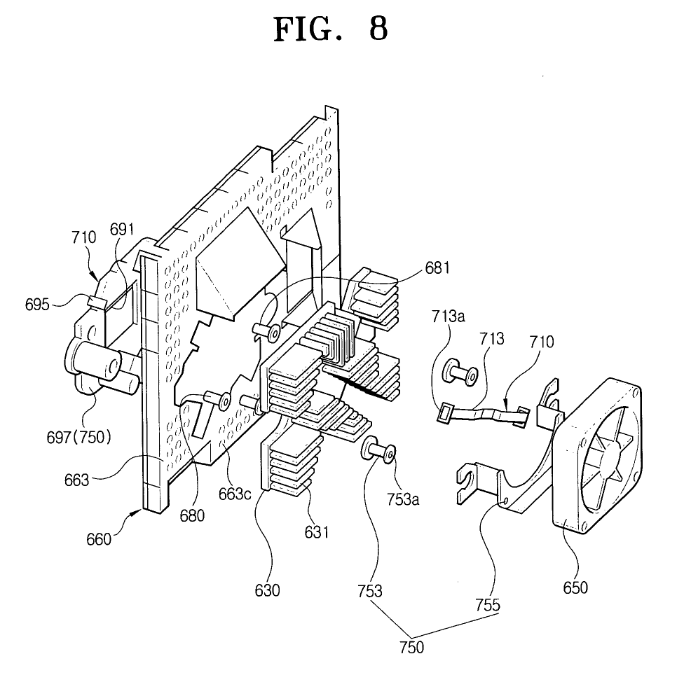

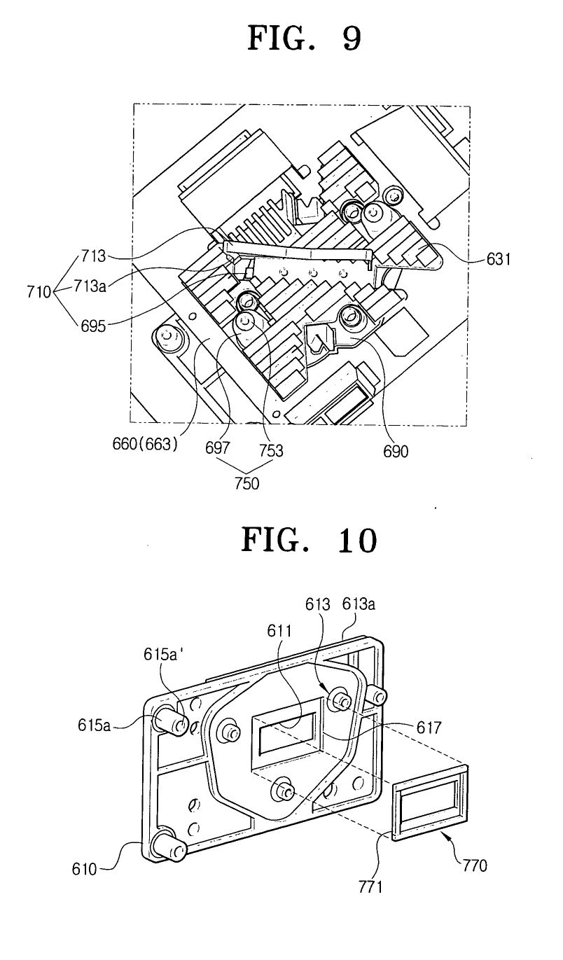

FIG. 8 is an enlarged view of a portion ‘V’ of FIG. 5, and FIG. 9 shows the heat sink 630 when it is connected.

Referring to FIGS. 7 to 9, the bracket plate 690 is partly exposed to the outside of the second square box 663 of the housing 660 and is connected with the heat sink 630 through a heat sink supporting unit 710. The heat sink supporting unit 710 comprises hooks 695 formed on a peripheral end of the bracket plate 690, and a flat spring 713 supporting one side of the heat sink 630 by crossing under the heat sink 630 and having hook recesses 713a for engagement with the hooks 695 at opposite ends thereof. The heat sink 630 comprises a plurality of protruding cooling fins 631.

With reference to FIGS. 5 and 8, the cooling fins 631 are mounted on one side of the heat sink 630 through a fan supporting unit 750. The fan supporting unit 750 comprises a fan supporting boss 697 protruding from the bracket plate 690, a fan holder 753 inserted in the fan supporting boss 697, and a fan bracket 755 connected to a bottom of the cooling fan 631 and engaged with the fan holder 753 at opposite ends of the fan holder. The bracket plate 690 is preferably made of aluminum due to its superior thermal conductivity. One end of the fan holder 753 is inserted in the fan supporting boss 697 while the other end is exposed to the outside of the fan supporting boss 697 and fit into a damper 753a.

Additionally, a substantially dustproof unit 770 is provided to the DMD 674 to block foreign substances and prevent them from flowing into the DMD 674.

FIG. 10 is an enlarged view of a portion ‘VI’ of FIG. 5 that illustrates a substantially dustproof unit applied in accordance with an exemplary embodiment of the present invention.

Referring to FIGS. 5 and 10, the substantially dustproof unit 770 comprises a gasket 771 formed as a substantially square frame for surrounding the DMD holder opening 675a of the DMD holder 675. The gasket 771 is preferably formed of resilient material. To mount the gasket 771, at least one of the optical holder 610 or the DMD holder 675 is provided with a groove 617 for insertion of the gasket 771. In the drawing, by way of example, the optical holder 610 has the groove 617. According to this structure, foreign substances such as dust can be effectively prevented from flowing into the DMD 674.

While the invention has been shown and described with reference to certain embodiments thereof, it will be understood by those skilled in the art that various changes in form and details may be made therein without departing from the spirit and scope of the invention as defined by the appended claims.

What is claimed is:

1. A digital micro-mirror device (DMD) assembly for an optical projection system, comprising:
a DMD module including a control board provided with a first fixing member, a DMD mounted on one side of the control board, and a DMD holder resiliently supporting a perimeter of the DMD;
an optical holder provided with a second fixing member to support the DMD module; and
a fastening member engaged with the first and the second fixing members to integrally connect the DMD module and the optical holder.

2. The DMD assembly of claim 1, wherein
a DMD holder opening is located in the central portion of the DMD holder, and
the DMD holder opening is provided with a plurality of decentralizing holes.

3. The DMD assembly of claim 1, wherein
the control board is provided with a bracket plate on the side opposite to the side where the DMD is mounted, and
the bracket plate has a third fixing member to integrally connect the bracket plate, the DMD module and the optical holder through the fastening member.

4. The DMD assembly of claim 1, wherein
the fastening member comprises a plurality of screws.

5. The DMD assembly of claim 4, wherein
the first fixing member comprises a plurality of board connection holes formed on the control board for engagement with the screws.

6. The DMD assembly of claim 4, wherein
the second fixing member comprises a plurality of holder connection holes protruding from the optical holder for engagement with the screws.

7. The DMD assembly of claim 4, wherein
the third fixing member comprises a plurality of bracket plate connection holes formed on the bracket plate.

8. The DMD assembly of claim 4, wherein
the DMD holder is provided with a plurality of via-holes to allow the screws to pass through.

9. The DMD assembly of claim 3, wherein
the bracket plate is made of aluminum.

10. The DMD assembly of claim 3, wherein
the bracket plate is connected with a heat sink by a heat sink supporting unit and is provided with a bracket plate opening so that a rear portion of the DMD can contact the heat sink.

11. The DMD assembly of claim 10, wherein the heat sink supporting unit comprises:
a plurality of hooks formed on a peripheral end of the bracket plate; and
a flat spring for supporting the heat sink and having hook recesses for engagement with the hooks at opposite ends of the flat spring.

12. The DMD assembly of claim 10, wherein
the heat sink has a cooling fan on one side which is supported by a fan supporting unit, and
the fan supporting unit comprises:
a cooling fan supporting boss protruding from the bracket plate;
a fan holder inserted in the cooling fan supporting boss; and
a fan bracket engaged with the fan holder at opposite ends of the fan bracket and connected to a bottom of the cooling fan.

13. The DMD assembly of claim 1, wherein
a substantially dustproof unit is provided between the DMD holder and the optical holder.

14. The DMD assembly of claim 13, wherein
the substantially dustproof unit comprises a gasket for surrounding the DMD holder opening of the DMD holder.

15. The DMD assembly of claim 14, wherein
the gasket is formed of resilient material.

16. The DMD assembly of claim 14, wherein
at least one of the optical holder and the DMD holder is provided with a groove for receiving the gasket.

17. The DMD assembly of claim 1, further comprising
a housing that encloses the DMD module and the DMD holder and has a plurality of housing connection holes thereon, and
wherein the optical holder further comprises a housing boss having boss holes corresponding to the housing connection holes, so that the housing and the optical holder can be integrally connected with each other.

18. The DMD assembly of claim 17, wherein
the housing comprises a plurality of cooling holes.

19. The DMD assembly of claim 17, wherein
the housing is formed of metal.

20. The DMD assembly of claim 17, wherein
the housing connection holes are larger than the boss holes so that the position of the housing can be adjusted.
